(19) United States
(12) Patent Application Publication
(10) Pub. No.: US 2026/0303068 A1
(43) Pub. Date: Oct. 1, 2026

(54) CLOCK GENERATION CIRCUIT AND SEMICONDUCTOR COMPONENTS

(71) Applicant: Winbond Electronics Corp., Taichung City (TW)

(72) Inventor: Yasue Yamamoto, Tokyo (JP)

(73) Assignee: Winbond Electronics Corp., Taichung City (TW)

(21) Appl. No.: 19/574,426

(22) Filed: Mar. 22, 2026

(30) Foreign Application Priority Data
Mar. 25, 2025 (JP) 2025-049256

(51) Int. Cl. H03K 3/011; H03K 3/03

(52) U.S. Cl. CPC H03K 3/011; H03K 3/0315

(57) ABSTRACT

A clock generation circuit that reduces frequency of a clock signal when a power supply voltage increases. The clock generation circuit of the disclosure includes a reference current setting unit, a bias voltage generation unit, and a ring oscillator. The bias voltage generation unit generates a PBIAS voltage applied to gates of PMOS transistors and an NBIAS voltage applied to gates of NMOS transistors in the ring oscillator. In response to the power supply voltage reaching a target voltage, the bias voltage generation unit increases the PBIAS voltage, thereby reducing a current supplied by the PMOS transistors and lowering frequency of the clock signal.

### CROSS-REFERENCE TO RELATED APPLICATION

This application claims the priority benefit of Japan application serial no. 2025-049256, filed on Mar. 25, 2025. The entirety of the above-mentioned patent application is hereby incorporated by reference herein and made a part of this specification.

### BACKGROUND

### Technical Field

This disclosure relates to a clock generation circuit, and particularly relates to a ring oscillator formed by connecting an odd number of inverters.

### Related Art

In semiconductor components such as memory or logic, ring oscillators that generate clock signals without requiring an external clock are used. A ring oscillator is constituted by connecting an odd number of inverters in series and feeding back the output of the last stage to the input of the first stage, and the frequency of the generated clock signal is determined by the delay time of the inverters and the number of inverters. The clock signal generated by the ring oscillator is utilized, for example, for generation of high voltage by a charge pump circuit.

### SUMMARY

FIG. 1 is a diagram showing a structure example of a conventional clock generation circuit. As shown in this figure, a clock generation circuit 10 includes a reference current setting unit 20, a bias voltage generation unit 30, and a ring oscillator 40. The reference current setting unit 20 includes a resistor R, a resistor R1, a resistor R2, a resistor R3, a resistor R4, and a diode-connected N-channel Metal Oxide Semiconductor (NMOS) transistor MN1 in a current path connected in series between a power supply voltage Vcc and GND (ground), and further includes transistors CP1 to CP4 connected in parallel with the resistors. The transistors CP1 to CP4 select a resistance between the power supply voltage Vcc and a node N1, and the transistor MN1 generates a reference current IREF corresponding to the voltage of the node N1 generated by the selected resistance.

The bias voltage generation unit 30 includes a P-channel Metal-Oxide-Semiconductor (PMOS) transistor MP2 and an NMOS transistor MN2 in a current path between the power supply voltage Vcc and GND. The transistor MP2 is diode-connected at a node N2, and the transistor MN2 and the transistor MN1 constitute a current mirror. The node N1 generates a gate voltage of the transistor MN2, that is, an N bias (NBIAS) voltage, and the node N2 generates a gate and drain voltage corresponding to the reference current IREF as a P bias (PBIAS) voltage.

The ring oscillator 40 includes an odd number (five in the example of the figure) of inverter stages, and an output of a final stage Complementary Metal Oxide Semiconductor (CMOS) inverter is connected to an input of the first CMOS inverter. One inverter stage includes: a PMOS transistor MP3 connected in series between the power supply voltage Vcc and the CMOS inverter, and an NMOS transistor MN3 connected in series between the CMOS inverter and GND. The PBIAS voltage is commonly applied to the gates of the transistors MP3 of each inverter stage, and the transistor MP3 and the transistor MP2 constitute a current mirror, the NBIAS voltage is commonly applied to the gates of the transistors MN3, and the transistor MP3 and the transistor MN2 constitute a current mirror.

The ring oscillator 40 controls frequency of a clock signal OSC through current control. That is, the frequency of the clock signal OSC output from an output buffer 42 is controlled through the current flowing through the transistor MP3 and the transistor MN3 biased by the PBIAS voltage and the NBIAS voltage. If the current supplied to the CMOS inverter through the transistor MP3 enlarges, the delay time caused by the charging and discharging of the CMOS inverter decreases, and the frequency of the clock signal OSC increases.

Ideally, the power supply voltage Vcc is fixed, but if it becomes higher than the desired voltage due to the influence of the operating environment or the like, the current supplied from the power supply voltage Vcc increases, the voltage of the node N1 increases, and the reference current IREF enlarges. If the reference current IREF enlarges, the PBIAS voltage decreases, the current flowing through the transistor MP3 of the ring oscillator 40 enlarges, and the frequency of the generated clock signal OSC increases. In a condition of driving the charge pump circuit using the clock signal OSC, as the frequency of the clock signal OSC increases, an output current Iout of the charge pump circuit increases, which will cause a consumption current or a peak current Icc of the charge pump circuit to increase. From the viewpoint of energy saving of the semiconductor component or protection of circuit components, the increase in consumption current or peak current Icc is also not ideal.

The purpose of the disclosure is to solve the above problems and provide a clock generation circuit and a semiconductor component that decrease the frequency of the clock signal when the power supply voltage increases.

The clock generation circuit of the disclosure includes: a ring oscillator having an odd number of inverter stages connected in series, the inverter stages including a PMOS transistor connected between a power supply voltage and a CMOS inverter; and a generation component that generates a first bias voltage commonly applied to gates of each PMOS transistor of the ring oscillator, the generation component increasing the first bias voltage in response to a condition that the power supply voltage has reached a target voltage.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a diagram representing a structure example of a conventional clock generation circuit.

FIG. 2 is a diagram representing a structure of a clock generation circuit of a first embodiment of the disclosure.

FIG. 3 is a diagram representing a generation example of a target voltage VDIV.

FIG. 4 is a chart representing a relationship between a PBIAS voltage and a NBIAS voltage and a power supply voltage Vcc.

FIG. 4A is a diagram representing a structure example of a charge pump circuit operated by a clock signal generated by a clock generation circuit of this embodiment.

(A) of FIG. 5 is a chart representing a relationship between frequency of a clock signal and an output current Iout of a charge pump circuit in a conventional example, and (B) of FIG. 5 is a chart representing a relationship between frequency of a clock signal and an output current Iout of a charge pump circuit in the first embodiment.

(A) of FIG. 6 is a diagram representing a structure of a clock generation circuit of a second embodiment of the disclosure, and (B) of FIG. 6 is a chart representing a relationship between a PBIAS voltage and a NBIAS voltage and a power supply voltage Vcc.

FIG. 7 is a chart representing a relationship between frequency of a clock signal and an output current Iout of a charge pump circuit in the second embodiment.

(A) of FIG. 8 is a diagram representing a structure of a clock generation circuit of a third embodiment of the disclosure, and (B) of FIG. 8 is a chart representing a relationship between a PBIAS voltage and a NBIAS voltage and a power supply voltage Vcc.

### DESCRIPTION OF THE EMBODIMENTS

The embodiment of the disclosure relates to a ring oscillator mounted in a semiconductor component such as a memory or logic. In one form, the clock signal generated by the ring oscillator is supplied to a charge pump circuit, and the charge pump circuit generates a high voltage required for writing of a flash memory. Hereinafter, embodiments of the disclosure will be described in detail with reference to the accompanying drawings.

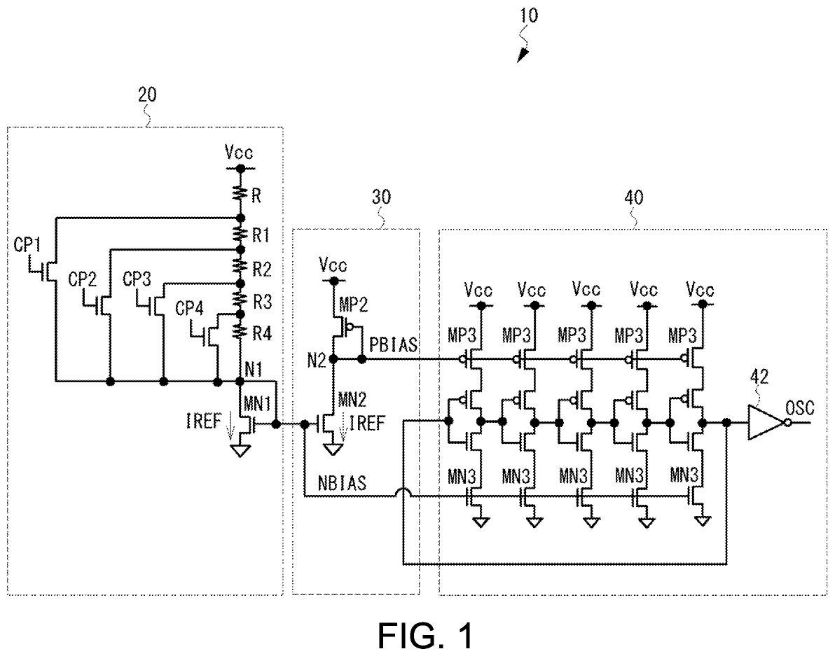

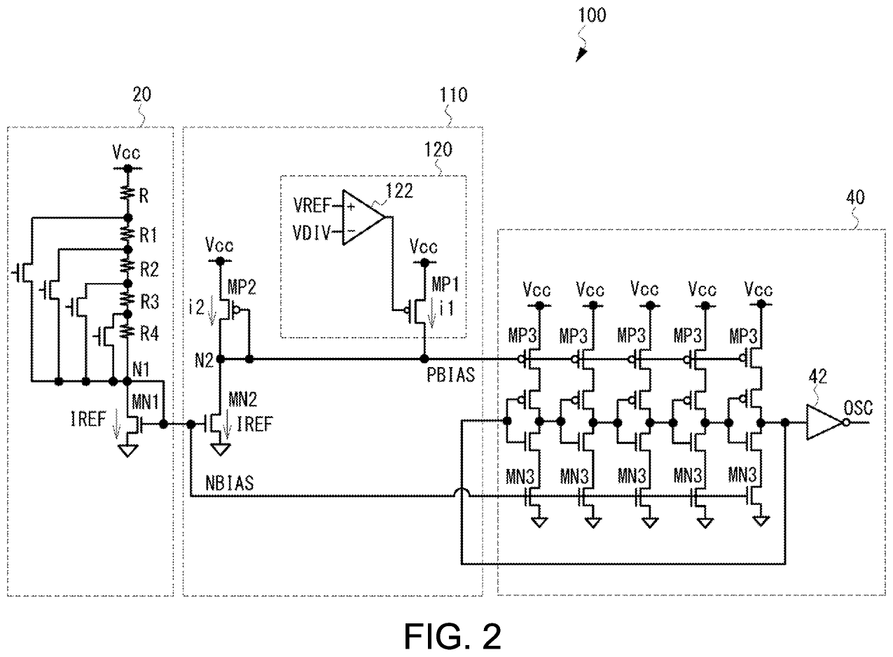

FIG. 2 is a diagram representing a structure of a clock generation circuit of a first embodiment of the disclosure. A clock generation circuit 100 of this embodiment is constituted including a reference current setting unit 20, a bias voltage generation unit 110 that generates a PBIAS voltage and a NBIAS voltage, and a ring oscillator 40. The reference current setting unit 20 and the ring oscillator 40 are the same as the structure described in FIG. 1, and the description thereof is omitted here.

The bias voltage generation unit 110 of this embodiment is similar to the structure of a bias voltage generation unit 30 shown in FIG. 1, and the difference is only that the bias voltage generation unit 110 includes a newly added current control unit 120. As shown in the diagram, the bias voltage generation unit 110 includes a PMOS transistor MP2 and an NMOS transistor MN2 diode-connected to the current path between a power supply voltage Vcc and GND, and further includes a current control unit 120 connected to a node N2. The node N2 where the transistor MP2 and the transistor MN2 are combined generates the PBIAS voltage. As described later, when the power supply voltage Vcc increases compared to the target voltage, the current control unit 120 supplies a current i1 to the node N2, thereby reducing a current i2 flowing to the diode-connected transistor MP2, thereby increasing the PBIAS voltage.

The transistor MN2 and the transistor MN1 of the reference current setting unit 20 constitute a current mirror, causing a reference current IREF to flow. For the node N2, the current i2 from the transistor MP2 and the current i1 from the current control unit 120 are supplied, and the following relational expression is established.

$$Reference current IREF = i 1 + i 2$$

$$i 2 = IREF - i 1$$

According to this relational expression, when the current control unit 120 supplies the current i1 to the node N2, the current i2 flowing through the diode-connected transistor MP2 becomes smaller, thereby, the PBIAS voltage of the node N2 becomes larger. When the PBIAS voltage becomes larger, the current supplied from the PMOS transistor MP3 of the ring oscillator 40 to the CMOS inverter is narrowed, and the frequency of a clock signal OSC becomes smaller.

The current control unit 120 supplies the current i1 when the power supply voltage Vcc increases, and this structure is not particularly defined, for example, the current control unit 120 is constituted including a differential amplifier 122 and a PMOS transistor MP1. The differential amplifier 122 has a non-inverting input terminal (+) receiving the reference voltage VREF, an inverting input terminal (−) receiving a target voltage VDIV, and an output connected to the gate of the transistor MP1.

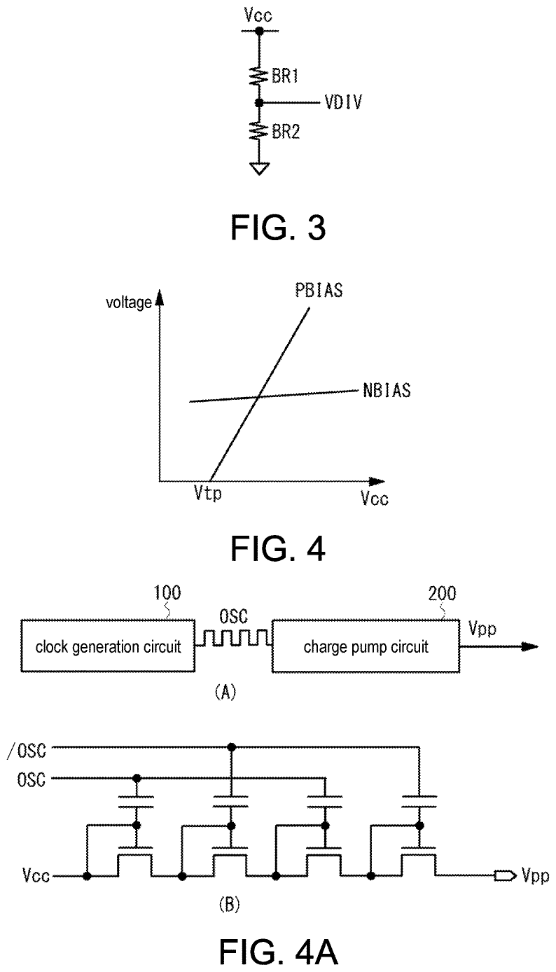

The reference voltage VREF is not particularly defined, for example, it is generated by a BGR circuit, and is VREF=1.1V. The target voltage VDIV is a voltage set to start the narrowing of the current by the transistor MP3 of the ring oscillator 40. The target voltage VDIV is generated, for example, by the resistive voltage division of a resistor BR1 and a resistor BR2 connected in series between the power supply voltage Vcc and GND as shown in FIG. 3. For example, if the charge pump circuit is designed assuming that the power supply voltage Vcc is 1.6V, the target voltage VDIV is set to become a desired voltage when the power supply voltage Vcc is 1.6V.

When the power supply voltage Vcc is 1.6V or less than 1.6V, a gate/source voltage Vgs of the transistor MP1 is greater than a threshold Vtp (Vgs>Vtp), and the transistor MP1 is turned off. Therefore, i1=0 and i2=IREF, the PBIAS voltage of the node N2 is the gate and drain voltage of the transistor MP2 corresponding to the current i2, and a desired current conforming to the design is supplied to the CMOS inverter of the ring oscillator 40.

When the power supply voltage Vcc exceeds 1.6V, a negative (minus) voltage corresponding to the difference between the reference voltage VREF and the target voltage VDIV is applied to the transistor MP1 by the differential amplifier 122, the gate/source voltage Vgs of the transistor MP1 becomes less than the threshold (Vgs<Vtp), the transistor MP1 is turned on and the current i1 flows. Since i2=IREF−i1, when the current i1 is supplied to the node N2, the current i2 flowing through the transistor MP2 decreases, and correspondingly, the PBIAS voltage of the node N2 becomes larger. Thereby, the current flowing through the transistor MP3 of the ring oscillator 40 is narrowed to become smaller, and the frequency of the generated clock signal OSC decreases. The current i1 flowing through the transistor MP1 is proportional to the increase of the power supply voltage Vcc, that is, as the power supply voltage Vcc becomes larger, the negative output voltage of the differential amplifier 122 becomes larger, and the current i1 becomes larger.

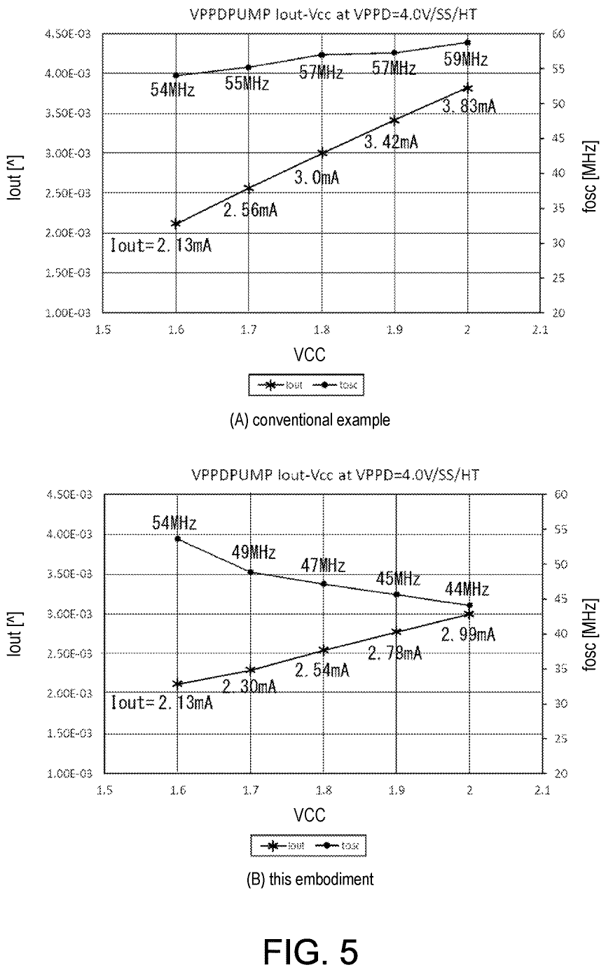

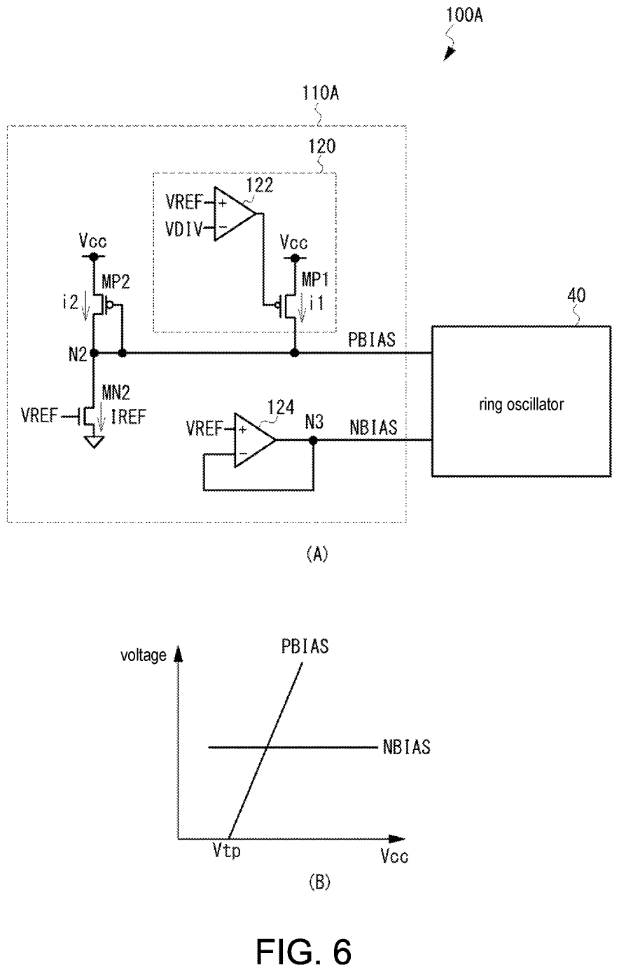

FIG. 4 is a chart representing a relationship between a PBIAS voltage and a NBIAS voltage and a power supply voltage Vcc. As described above, when the power supply voltage Vcc exceeds 1.6V, the current control unit 120 becomes Vgs>Vtp, the transistor MP1 is turned on, and the current i1 is supplied to the node N2, thereby, the current i2 flowing through the transistor MP2 decreases by the amount of the current i1, and the PBIAS voltage becomes larger. On the other hand, when the power supply voltage Vcc increases, the voltage of a node N1 of the reference current setting unit 20 becomes larger, therefore the NBIAS voltage also has a slightly positive slope.

When the power supply voltage Vcc exceeds 1.6V, the PBIAS voltage of the ring oscillator 40 increases, therefore the current flowing through the transistor MP3 decreases, the delay caused by the CMOS inverter becomes larger, as a result, the frequency of the output clock signal OSC decreases.

The clock signal OSC output from the clock generation circuit 100 is provided to the charge pump circuit 200 as shown in (A) of FIG. 4A, and the charge pump circuit 200 uses the clock signal OSC to generate a high voltage Vpp. The high voltage Vpp is utilized for, for example, a write voltage or an erase voltage of a flash memory.

(B) of FIG. 4A represents an example of the charge pump circuit. The charge pump circuit 200 includes, for example, multiple diode-connected MOS transistors, and each MOS transistor is connected in series. Capacitors are connected to the gates of the MOS transistors, the clock signal OSC is applied to each capacitor of the odd-numbered MOS transistors, and a clock signal/OSC is applied to each capacitor of the even-numbered MOS transistors. The clock signal OSC and the clock signal/OSC are in a relationship of 180 degrees out of phase. The charge pump circuit 200 inputs, for example, the power supply voltage Vcc, and outputs a boosted high voltage Vpp.

(A) of FIG. 5 is a chart representing a relationship between a frequency fosc of the clock signal OSC and an output current (drive current) Iout of the charge pump circuit in a conventional example, and (B) of FIG. 5 is a chart representing a relationship between the frequency fosc of the clock signal OSC and the output current Iout of the charge pump circuit in the first embodiment.

In the conventional example, when the power supply voltage Vcc is 1.6V, the frequency of the clock signal is 54 MHz, and the output current Iout of the charge pump circuit operating with this clock signal is 2.13 mA. Furthermore, as the power supply voltage Vcc becomes larger, the frequency of the clock signal becomes higher, and the output current Iout of the charge pump circuit becomes proportionally larger.

For example, if the charge pump circuit is designed assuming the condition of operating at a power supply voltage Vcc of 1.6V, it is sufficient as long as the output current Iout=2.13 mA can be obtained, and an output current Iout exceeding this is not required. That is, when the power supply voltage Vcc rises from 1.6V to 2.0V, the output current Iout of the charge pump circuit increases significantly from 2.13 mA to 3.83 mA, but the output current exceeding 2.13 mA may become useless current.

In contrast, in this embodiment, when the power supply voltage Vcc increases from 1.6V to 2.0V, the frequency of the clock signal decreases from 54 MHz to 44 MHz, and the output current Iout of the charge pump circuit only increases from 2.13 mA to 2.99 mA. Thereby, even if the power supply voltage Vcc increases, since the frequency of the clock signal decreases, compared with the conventional example, this embodiment may reduce the amplitude of increase in the output current Iout and suppress the current consumption.

Next, the second embodiment of the disclosure will be described. (A) of FIG. 6 is a diagram representing a structure of a clock generation circuit of a second embodiment. As shown, a bias voltage generation unit 110A includes a PMOS transistor MP2 and an NMOS transistor MN2 diode-connected to the current path between the power supply voltage Vcc and GND, and further includes a current control portion 120 connected to the node N2. The node N2 where the transistor MP2 and the transistor MN2 are combined generates the PBIAS voltage. In the second embodiment, the reference voltage VREF is applied to the gate of the transistor MN2, the transistor MN2 generates a reference current IREF corresponding to the reference voltage VREF, and the PBIAS voltage is generated at the node N2. Similar to the first embodiment, when the current control portion 120 conducts the transistor MP1 when the power supply voltage Vcc exceeds the assumed voltage (for example, 1.6V), the current i1 is supplied to the node N2, thereby the current i2 flowing through the transistor MP2 is reduced by the amount of the current i1, and the PBIAS voltage becomes larger.

The bias voltage generation unit 110A further includes a unity gain buffer 124, generates the reference voltage VREF at a node N3, and supplies this reference voltage VREF as the NBIAS voltage to the ring oscillator 40. The method of generating the reference voltage VREF is not particularly defined, for example, it is ideal to use a BGR circuit (bandgap reference circuit) to generate a reference voltage that has no dependency on variations in the power supply voltage or temperature.

(B) of FIG. 6 is a chart representing a relationship between a PBIAS voltage and a NBIAS voltage and the power supply voltage Vcc. In the second embodiment, different from the first embodiment, even if the power supply voltage Vcc increases, the NBIAS voltage remains substantially constant. Moreover, since the reference current IREF flowing through the transistor MN2 does not depend on the power supply voltage Vcc and is constant, the amplitude of decrease in the current i2 becomes larger accompanying the increase in the power supply voltage Vcc, as a result, the slope of the PBIAS voltage is slightly larger than that in the first embodiment, and correspondingly, the narrowing of the current supplied to the CMOS inverter of the ring oscillator 40 becomes larger. That is, the frequency of the clock signal generated by the ring oscillator 40 decreases compared to that in the first embodiment.

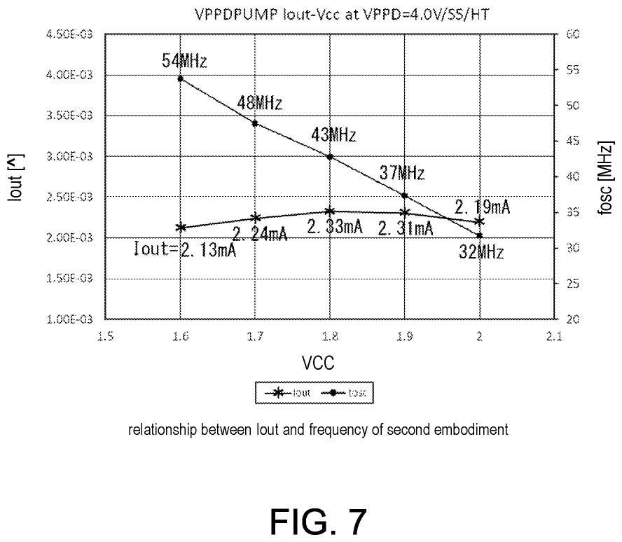

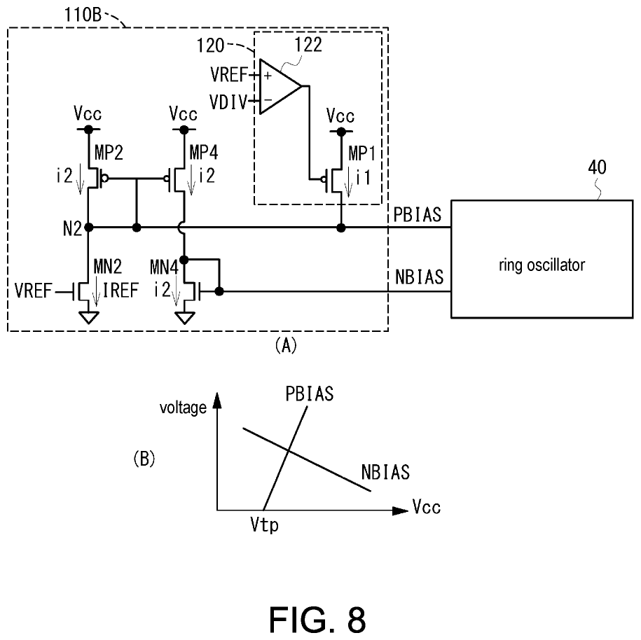

FIG. 7 is a chart representing a relationship between the frequency fosc of the clock signal OSC and the output current Iout of the charge pump circuit in the second embodiment. In the second embodiment, when the power supply voltage Vcc increases from 1.6 V to 2.0 V, the frequency of the clock signal decreases from 54 MHz to 32 MHz, and the output current Iout of the charge pump circuit is suppressed from 2.13 mA to only increase to 2.19 mA. Compared with the conventional example of (A) of FIG. 5, this embodiment may reduce the amplitude of increase in the output current Iout and suppress the consumption of current.

Next, a third embodiment of the disclosure is described. (A) of FIG. 8 is a diagram representing a structure of a clock generation circuit of a third embodiment. As shown, a bias voltage generation unit 110B includes a PMOS transistor MP2 and an NMOS transistor MN2 diode-connected to a current path between the power supply voltage Vcc and GND, and further includes a current control portion 120 connected to the node N2. The node N2 where the transistor MP2 and the transistor MN2 are combined generates the PBIAS voltage. In the third embodiment, the reference voltage VREF is applied to the gate of the transistor MN2, the transistor MN2 generates a reference current IREF corresponding to the reference voltage VREF, and the PBIAS voltage is generated at the node N2. The bias voltage generation unit 110B further includes a PMOS transistor MP4 and an NMOS transistor MN4 diode-connected to a current path between the power supply voltage Vcc and GND. The transistor MP2 and the transistor MP4 constitute a current mirror. The transistor MN4 and the transistor MN3 of the ring oscillator 40 constitute a current mirror, and the NBIAS voltage is generated at the drain and gate node of the transistor MN4.

For example, when the current control portion 120 conducts the transistor MP1 when the power supply voltage Vcc exceeds an assumed voltage (for example, 1.6 V), the current i1 is supplied to the node N2, whereby the current i2 flowing through the transistor MP2 decreases by the amount of the current i1, the PBIAS voltage enlarges, and the current supplied from the transistor MP3 of the ring oscillator 40 narrows. At the same time, the current i2 flowing to the transistor MP4 decreases, so the drain and gate voltage (i.e., the NBIAS voltage) of the diode-connected transistor MN4 decreases. Thereby, the current flowing from the transistor MN3 of the ring oscillator 40 to GND narrows. (B) of FIG. 8 is a chart representing a relationship between the PBIAS voltage and the NBIAS voltage and the power supply voltage Vcc. In the third embodiment, when the power supply voltage Vcc exceeds 1.6 V, the PBIAS voltage has a positive slope, and the NBIAS voltage has a negative slope. By appropriately setting the slopes of the PBIAS voltage and the NBIAS voltage, optimization of the frequency of the clock signal of the ring oscillator may be implemented.

In the embodiment, the frequency of the clock signal or the output current/peak current of the charge pump circuit when the power supply voltage Vcc is 1.6 V is exemplified, but the disclosure is of course not defined to these examples. Furthermore, an example in which the ring oscillator includes five inverter stages is represented, but the disclosure is not defined to this.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A clock generation circuit, comprising:
a ring oscillator, having an odd number of inverter stages connected in series, the inverter stages comprising a P-channel metal oxide semiconductor transistor connected between a power supply voltage and a complementary metal oxide semiconductor inverter;
a generation component, generating a first bias voltage commonly applied to gates of the P-channel metal oxide semiconductor transistors of the ring oscillator; and
a detection component, comprising an operational amplifier detecting an increase of the power supply voltage and a first transistor having a gate connected to an output of the operational amplifier,
wherein the generation component enlarges the first bias voltage according to a first current flowing through the first transistor.

2. The clock generation circuit according to claim 1, wherein the operational amplifier is a differential amplifier inputting a reference voltage and a voltage obtained by resistive voltage division of the power supply voltage.

3. The clock generation circuit according to claim 1, wherein the generation component further comprises a second transistor diode-connected between the power supply voltage and a node, the second transistor and the first transistor being connected at the node, the node generating the first bias voltage,
a second current flowing to the second transistor is controlled through the first current, and the first bias voltage is controlled through the second current.

4. The clock generation circuit according to claim 3, wherein the generation component further comprises a third transistor connected between the node and a reference potential, the third transistor causing a reference current to flow at the reference potential, and
a relationship of second current=reference current-first current is established.

5. The clock generation circuit according to claim 1, wherein the inverter stages further comprise an N-channel metal oxide semiconductor transistor between the complementary metal oxide semiconductor inverter and a reference potential,
the generation component generates a second bias voltage commonly applied to gates of the N-channel metal oxide semiconductor transistors of the ring oscillator.

6. The clock generation circuit according to claim 5, wherein the generation component comprises a unity gain buffer, and the second bias voltage is generated at an output of the unity gain buffer.

7. The clock generation circuit according to claim 5, wherein the generation component comprises a second transistor diode-connected between the power supply voltage and a node, the second transistor and the first transistor being connected at the node, and the second bias voltage is generated based on a third current flowing through a fourth transistor replicating a second current generated by the second transistor.

8. The clock generation circuit according to claim 7, wherein the generation component further comprises a fifth transistor diode-connected to the fourth transistor, and a drain and gate voltage of the fifth transistor generates the second bias voltage.

9. The clock generation circuit according to claim 8, wherein the second bias voltage has a negative slope when the power supply voltage increases.

10. A semiconductor component, comprising:
the clock generation circuit according to claim 1; and
a charge pump circuit, operating using a clock signal generated by the clock generation circuit.

11. A semiconductor component, comprising:
the clock generation circuit according to claim 2; and
a charge pump circuit, operating using a clock signal generated by the clock generation circuit.

12. A semiconductor component, comprising:
the clock generation circuit according to claim 3; and
a charge pump circuit, operating using a clock signal generated by the clock generation circuit.

13. A semiconductor component, comprising:
the clock generation circuit according to claim 4; and
a charge pump circuit, operating using a clock signal generated by the clock generation circuit.

14. A semiconductor component, comprising:
the clock generation circuit according to claim 5; and
a charge pump circuit, operating using a clock signal generated by the clock generation circuit.

15. A semiconductor component, comprising:
the clock generation circuit according to claim 6; and
a charge pump circuit, operating using a clock signal generated by the clock generation circuit.

16. A semiconductor component, comprising:
the clock generation circuit according to claim 7; and
a charge pump circuit, operating using a clock signal generated by the clock generation circuit.

17. A semiconductor component, comprising:
the clock generation circuit according to claim 8; and
a charge pump circuit, operating using a clock signal generated by the clock generation circuit.

18. A semiconductor component, comprising:
the clock generation circuit according to claim 9; and
a charge pump circuit, operating using a clock signal generated by the clock generation circuit.
